(19) United States
(12) Patent Application Publication
(10) Pub. No.: US 2010/0295134 A1
(43) Pub. Date: Nov. 25, 2010

(54) SEMICONDUCTOR MEMORY DEVICE AND METHOD OF FABRICATING THE SAME

(76) Inventors: Satoshi Nagashima, Kanagawa (JP); Fumitaka Arai, Kanagawa (JP); Hisataka Meguro, Mie (JP); Hiroshi Akahori, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/560,313

(22) Filed: Sep. 15, 2009

(30) Foreign Application Priority Data
May 20, 2009 (JP) 2009-122191

(51) Int. Cl. H01L 27/11; H01L 21/8239

(52) U.S. Cl. 257/390; 438/279; 257/E27.098; 257/E21.645

(57) ABSTRACT

A semiconductor memory device according to one embodiment includes: a semiconductor substrate having an active region divided by an element isolation region; a plurality of stacked-gate type memory cell transistors connected in series on the active region; select transistors connected to both ends of the plurality of memory cell transistors on the active region; and a bit line contact connected to a drain region belonging to the select transistor in the active region, a vertical cross sectional shape of a lower portion of the bit line contact in a channel width direction of the plurality of memory cell transistors being in a skirt shape.

### CROSS-REFERENCE TO RELATED APPLICATIONS

This application is based upon and claims the benefit of priority from prior Japanese Patent Application No. 2009-122191, filed on May 20, 2009, the entire contents of which are incorporated herein by reference.

### BACKGROUND

A NAND-type flash memory is known as a conventional semiconductor memory device. The NAND-type flash memory, for example, is disclosed in JP-A 2009-49235. The NAND-type flash memory has plural memory cell transistors connected in series and select transistors connected to both ends thereof, and a source line contact connected to a source line and a bit line contact connected to a bit line are respectively connected to the select transistors located at the both ends.

A conventional bit line contact is formed by forming a contact hole having a bit line contact pattern in an insulating layer and then embedding a conductive material into the contact hole. Thus, a diameter of bottom of the bit line contact is smaller than that of an upper portion thereof.

As a result, a connected area of the bit line contact with a source/drain region included in an active region decreases, and electric resistance of a connected portion may be thereby increased.

In addition, when the bit line contact pattern is microscopic, an aspect ratio of the contact hole is increased, and embedding failure of the conductive material may thereby occur. If a void is generated in the bit line contact due to the embedding failure of the conductive material, electric resistance of the bit line contact is increased.

Furthermore, when the aspect ratio of the contact hole is large, it is difficult to remove an impurity at the bottom of the contact hole, and the electric resistance of a connected portion of the bit line contact with the source/drain region may be increased due to the impurity.

### BRIEF SUMMARY

A semiconductor memory device according to one embodiment includes: a semiconductor substrate having an active region divided by an element isolation region; a plurality of stacked-gate type memory cell transistors connected in series on the active region; select transistors connected to both ends of the plurality of memory cell transistors on the active region; and a bit line contact connected to a drain region belonging to the select transistor in the active region, a vertical cross sectional shape of a lower portion of the bit line contact in a channel width direction of the plurality of memory cell transistors being in a skirt shape.

A method of fabricating a semiconductor memory device according to another embodiment includes: forming a plurality of stacked-gate type memory cell transistors on an active region in a semiconductor substrate so as to be connected in series, select transistors on the active region so as to be connected to both ends of the plurality of memory cell transistors, a drain region belonging to the select transistor in the active region, and an insulating layer covering the plurality of memory cell transistors and the select transistors; forming a trench in a region of the insulating layer including a region on the drain region, the trench having a pattern of which a longitudinal direction corresponds to a channel width direction of the plurality of memory cell transistors; embedding a conductive material into the trench; shaping the conductive material into a bit line contact connected on the drain region by applying etching; and embedding an insulating material in a region of the trench where the conductive material has been removed by the shaping.

A method of fabricating a semiconductor memory device according to another embodiment includes: forming a plurality of first and second memory cell transistors on respective first and second active regions adjacent to each other via an element isolation region in a semiconductor substrate, first and second select transistors on the respective first and second active regions so as to be respectively connected to both ends of the plurality of first and second memory cell transistors, first and second drain regions respectively belonging to the first and second select transistors in the respective first and second active regions, and an insulating layer covering the plurality of first and second memory cell transistors and the first and second select transistors; forming a trench in a region of the insulating layer including a region on the first and second drain regions, the trench having a pattern of which a longitudinal direction corresponds to a channel width region of the plurality of first and second memory cell transistors; embedding a conductive material into the trench; shaping the conductive material by etching for forming first and second bit line contacts respectively connected on the first and second drain regions; and embedding an insulating material in a region of the trench where the conductive material has been removed by the process.

A semiconductor memory device according to another embodiment includes: a semiconductor substrate having an active region divided by an element isolation region; a stacked-gate type memory cell transistor on the active region; select transistor connected to an end of the memory cell transistor on the active region; and a bit line contact connected to a source/drain region belonging to the select transistor in the active region, a vertical cross sectional shape of a lower portion of the bit line contact in a channel width direction of the memory cell transistor being in a skirt shape.

A method of fabricating a semiconductor memory device according to another embodiment includes: forming a stacked-gate type memory cell transistor on an active region in a semiconductor substrate, select transistor on the active region so as to be connected to an end of the memory cell transistor, a source/drain region belonging to the select transistor in the active region, and an insulating layer covering the memory cell transistor and the select transistor; forming a trench in a region of the insulating layer including a region on the source/drain region, the trench having a pattern of which a longitudinal direction corresponds to a channel width direction of the memory cell transistor; embedding a conductive material into the trench; shaping the conductive material into a bit line contact connected on the source/drain region by applying etching; and embedding an insulating material in a region of the trench where the conductive material has been removed by the shaping.

A method of fabricating a semiconductor memory device according to another embodiment includes: forming first and second memory cell transistors on respective first and second active regions adjacent to each other via an element isolation region in a semiconductor substrate, first and second select transistors on the respective first and second active regions so as to be respectively connected to ends of the first and second memory cell transistors, first and second source/drain regions respectively belonging to the first and second select transistors in the respective first and second active regions, and an insulating layer covering the first and second memory cell transistors and the first and second select transistors; forming a trench in a region of the insulating layer including a region on the first and second source/drain regions, the trench having a pattern of which a longitudinal direction corresponds to a channel width region of the first and second memory cell transistors; embedding a conductive material into the trench; shaping the conductive material by etching for forming first and second bit line contacts respectively connected on the first and second source/drain regions; and embedding an insulating material in a region of the trench where the conductive material has been removed by the process.

### BRIEF DESCRIPTION OF THE DRAWING

FIG. 1 is a top view showing a semiconductor memory device according to a first embodiment;

FIGS. 2A to 2C are cross sectional views showing the semiconductor memory device 100 taken on lines A-A, B-B and C-C of FIG. 1;

FIGS. 3A to 3C are views showing processes for fabricating the semiconductor memory device according to the first embodiment;

FIGS. 4A to 4C are views showing processes for fabricating the semiconductor memory device according to the first embodiment;

FIGS. 5A to 5C are views showing processes for fabricating the semiconductor memory device according to the first embodiment;

FIGS. 6A to 6C are views showing processes for fabricating the semiconductor memory device according to the first embodiment;

FIGS. 7A to 7C are views showing processes for fabricating the semiconductor memory device according to the first embodiment;

FIGS. 8A to 8C are views showing processes for fabricating the semiconductor memory device according to the first embodiment;

FIGS. 9A to 9C are views showing processes for fabricating the semiconductor memory device according to the first embodiment;

FIGS. 10A to 10C are views showing processes for fabricating the semiconductor memory device according to the first embodiment;

FIGS. 11A to 11C are views showing processes for fabricating the semiconductor memory device according to the first embodiment;

FIGS. 12A and 12B are views showing processes for fabricating the semiconductor memory device according to the first embodiment;

FIGS. 13A and 13B are views showing processes for fabricating the semiconductor memory device according to the first embodiment;

FIGS. 14A to 14D are cross sectional views showing processes for fabricating the semiconductor memory device according to a second embodiment;

FIGS. 15A to 15C are views showing processes for fabricating the semiconductor memory device according to a third embodiment;

FIGS. 16A to 16C are views showing processes for fabricating the semiconductor memory device according to the third embodiment;

FIGS. 17A to 17C are views showing processes for fabricating the semiconductor memory device according to the third embodiment; and

FIG. 18 is a cross sectional view showing the semiconductor memory device according to a fourth embodiment.

### DETAILED DESCRIPTION

### First Embodiment

The first embodiment is one aspect of applying the present embodiment to a NAND-type flash memory device.

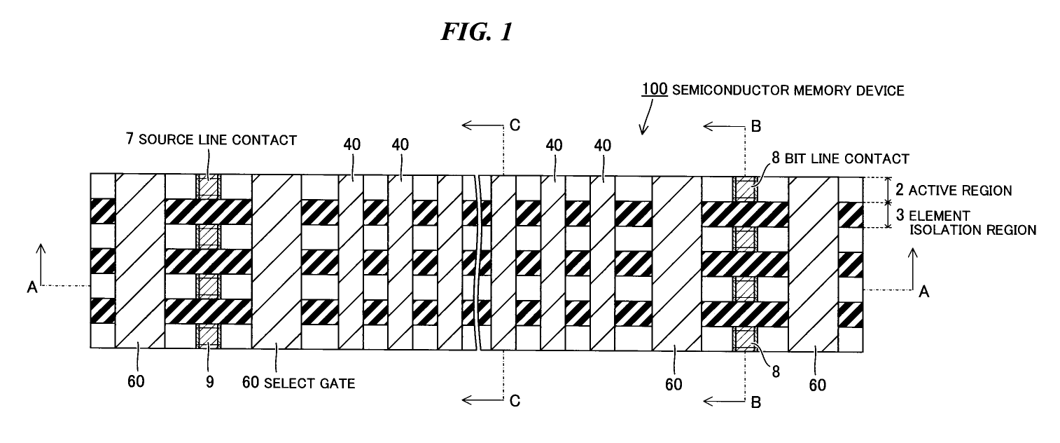

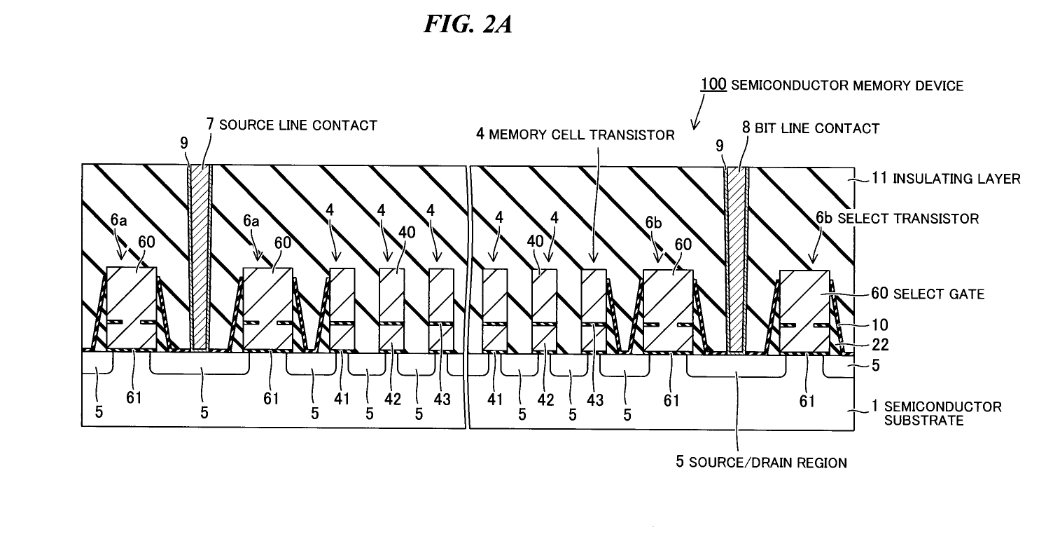

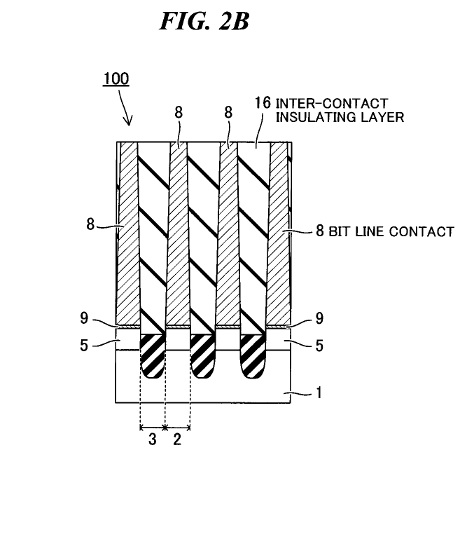

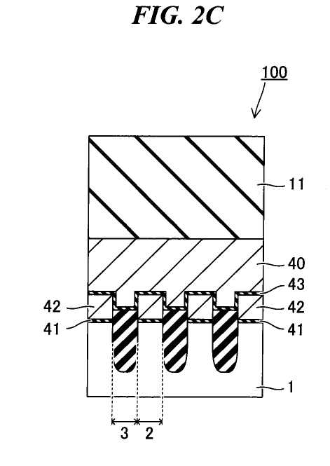

FIG. 1 is a top view showing a semiconductor memory device 100 according to a first embodiment. In addition, FIG. 2A is a cross sectional view showing the semiconductor memory device 100 taken on line A-A of FIG. 1, FIG. 2B is a cross sectional view showing the semiconductor memory device 100 taken on line B-B of FIG. 1, and FIG. 2C is a cross sectional view of the semiconductor memory device 100 taken on line C-C of FIG. 1.

The semiconductor memory device 100 has a semiconductor substrate 1, an element isolation region 3 for dividing plural active regions 2 on the semiconductor substrate 1, plural stacked-gate type memory cell transistors 4 formed on the active region 2 so as to be connected in series, select transistors 6a and 6b formed on the active region 2 at both ends of the plural memory cell transistors 4, a source line contact 7 and a bit line contact 8 respectively connected to a source/drain regions 5 provided adjacent to the select transistors 6a and 6b, an etching stopper film 10 formed on a spacer 22, an insulating layer 11 covering the plural memory cell transistors 4 and the select transistors 6a and 6b, and an inter-contact insulating layer 16 formed between the adjacent bit line contacts 8. Note that, in FIG. 1, illustrations of the spacer 22, the etching stopper film 10, the insulating layer 11 and the inter-contact insulating layer 16 are omitted.

Each memory cell transistor 4 has a gate insulating film 41 on the semiconductor substrate 1, a floating gate 42 on the gate insulating film 41, an intergate insulating film 43 on the floating gate 42, and a control gate 40 on the intergate insulating film 43.

The plural memory cell transistors 4 on one active region 2 are connected in series between the select transistors 6a and 6b via the source/drain region 5. In addition, the plural memory cell transistors 4 adjacent in a channel width direction of the memory cell transistor 4 (a vertical direction in FIG. 1) via the element isolation region 3 share the control gate 40.

The select transistors 6a and 6b have a gate insulating film 61 on the semiconductor substrate 1 and a select gate 60 on the gate insulating film 61.

The select transistors 6a and 6b are connected in series to memory cell transistors 4, which are located at both ends of the plural memory cell transistors 4 connected in series, via the source/drain region 5. In addition, plural select transistors 6a and 6b adjacent in the channel width direction via the element isolation region 3 respectively share the select gate 60 thereof.

In addition, the select transistor 6a is connected to adjacent another select transistor 6a via the source/drain region 5 on the active region 2. In the same way, the select transistor 6b is connected to adjacent another select transistor 6b via the source/drain region 5 on the active region 2. Furthermore, other plural memory cell transistors 4 (not shown) connected in series are respectively connected to another select transistors 6a and 6b.

In the source/drain region 5 belonging to the select transistor 6a, a region to be connected to the source line contact 7 functions as a source region of the select transistor 6a. Meanwhile, in the source/drain region 5 belonging to the select transistor 6b, a region to be connected to the bit line contact 8 functions as a drain region of the select transistor 6b.

The semiconductor substrate 1 is made of a Si-based single crystal such as a Si crystal, etc., or a Si-based polycrystal.

The element isolation region 3 has, e.g., a STI (Shallow Trench Isolation) structure made of an insulation material such as SiO₂, etc.

The gate insulating film 41 and the intergate insulating film 43 of the memory cell transistor 4 are made of an insulation material such as SiO₂, etc. Meanwhile, the control gate 40 and the floating gate 42 are made of, e.g., a Si-based material such as polycrystalline Si, etc., or a metal material (W, WSi, Ti, TiN, Ta, TaN, Al or Cu, etc.). Note that, a silicide layer containing a metal such as Ni, Pt, Ti or Co, etc., may be formed on an upper portion of the control gate 40.

The source/drain region 5 is formed by, e.g., implanting a conductivity type impurity into a surface of the semiconductor substrate 1 using an ion implantation method.

The gate insulating film 61 of the select transistors 6a and 6b is made of an insulation material such as SiO₂, etc. Meanwhile, the select gate 60 is made of, e.g., a Si-based material such as polycrystalline Si, etc., or a metal material (W, WSi, Ti, TiN, Ta, TaN, Al or Cu, etc.). Note that, a silicide layer containing a metal such as Ni, Pt, Ti or Co, etc., may be formed on an upper portion of the select gate 60.

The source line contact 7 and the bit line contact 8 are made of a conductive material such as W, etc. In addition, bottoms and side faces of the source line contact 7 and the bit line contact 8 are each covered by a barrier metal 9. The barrier metal 9 is made of a conductive material such as Ti, TiN or Co., etc.

As shown in FIG. 2B, a vertical cross sectional shape of the bit line contact 8 in a channel width direction is a skirt shape which expands in a taper shape. A vertical cross sectional shape of at least a lower portion of the bit line contact 8 in the channel width direction becomes a skirt shape due to manufacturing processes.

Alternatively, the source line contact 7 may have the same shape as the bit line contact 8. However, in general, it is not necessary to form a source line contact for each bit line, and one source line contact can be shared by plural bit lines. Therefore, the source line contact 7 does not necessarily have the same shape as the bit line contact 8.

The insulating layer 11 is made of an insulation material such as SiO₂, etc.

An example of a method of fabricating a semiconductor memory device 100 according to the present embodiment will be described hereinafter.

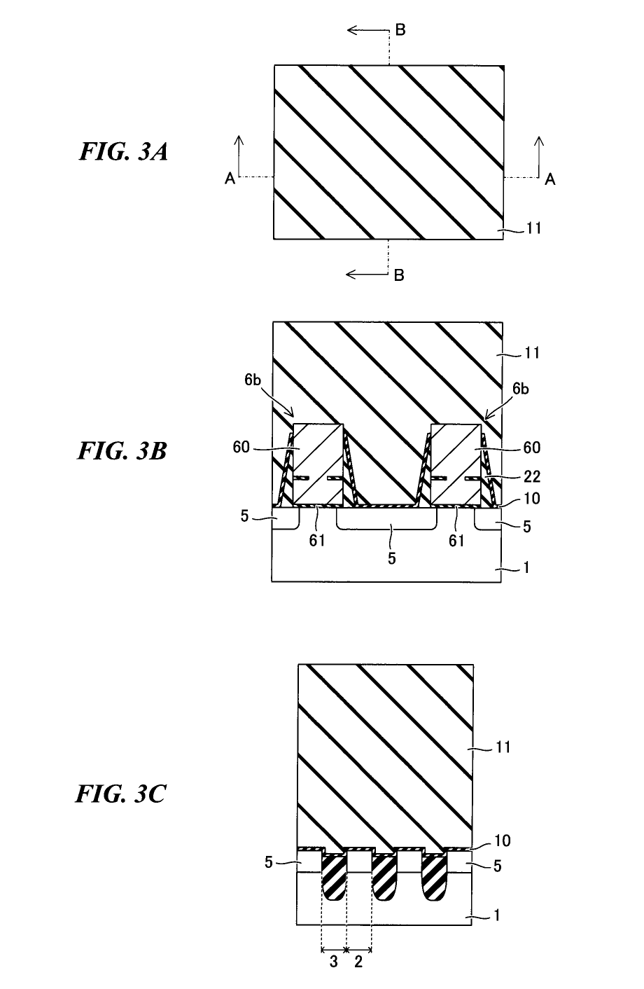

FIGS. 3 to 11 are views showing processes for fabricating the semiconductor memory device 100 according to the first embodiment. In FIGS. 3 to 11, FIGS. 3A to 11A are top views showing a vicinity of a region where the bit line contact 8 is formed. In addition, FIGS. 3B to 11B are cross sectional views of the region shown in FIGS. 3A to 11A taken on line A-A. In addition, FIGS. 3C to 11C are cross sectional views of the region shown in FIGS. 3A to 11A taken on line B-B. Note that, the lines A-A and B-B in FIGS. 3A to 11A correspond to lines A-A and B-B in FIG. 1, respectively.

Firstly, as shown in FIGS. 3A to 3C, the element isolation region 3 for dividing the plural active regions 2, the plural memory cell transistors 4, the source/drain region 5, the select transistor 6b, the spacer 22, the etching stopper film 10 and the insulating layer 11 are formed on the semiconductor substrate 1.

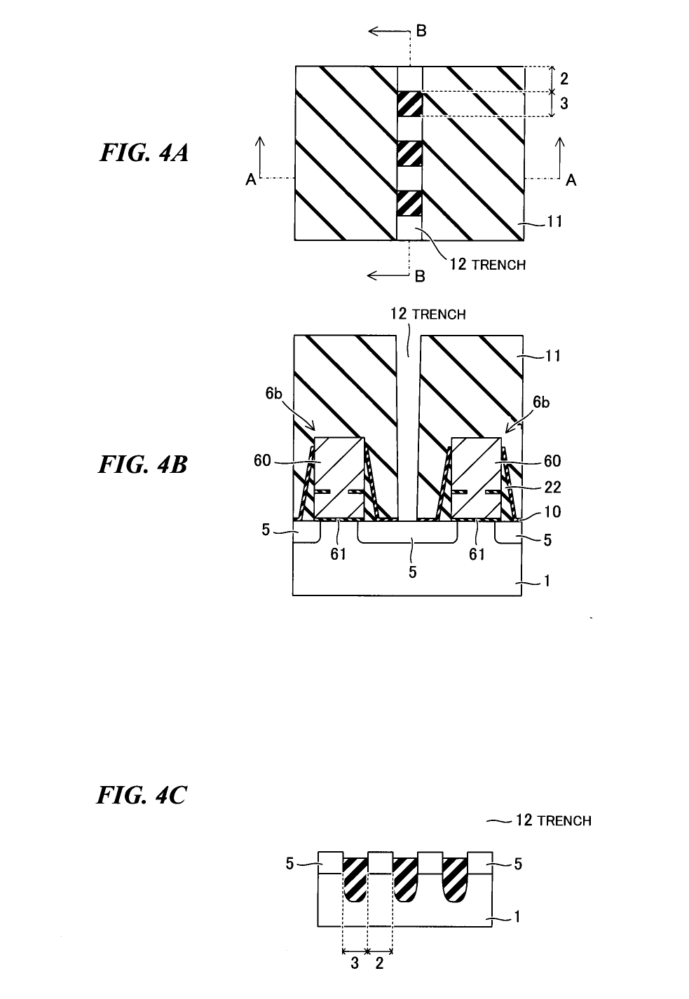

Next, as shown in FIGS. 4A to 4C, the insulating layer 11 and the etching stopper film 10 between two adjacent select transistors 6b are removed, thereby forming a trench 12. The trench 12 is formed by, e.g., a photolithography method and a RIE (Reactive Ion Etching) method. The trench 12 has a linear pattern of which the longitudinal direction corresponds to the channel width direction.

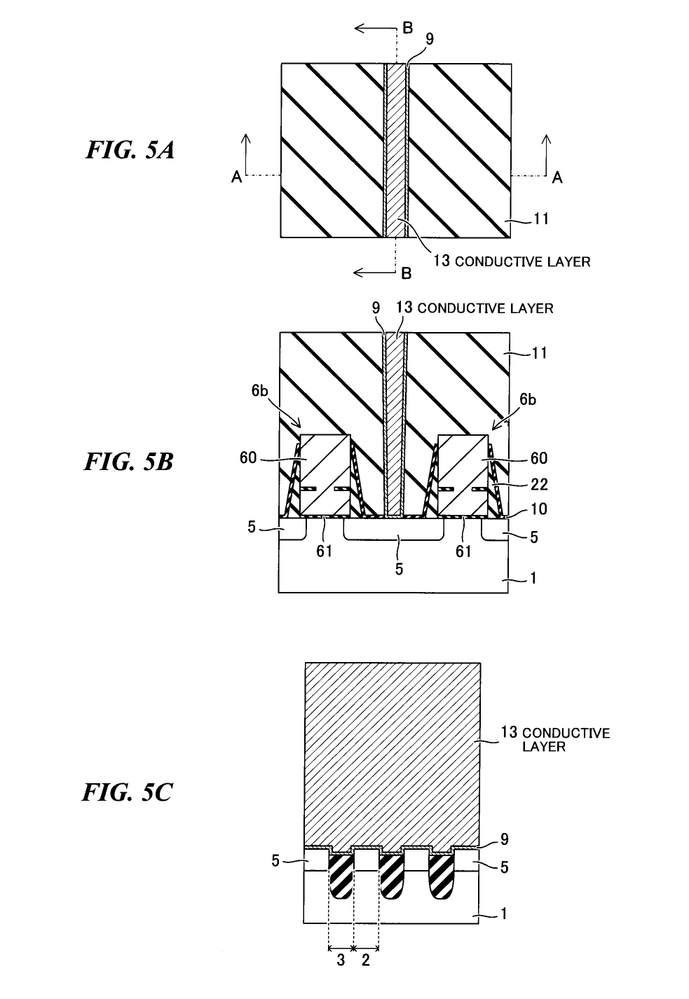

Next, as shown in FIGS. 5A to 5C, a conductive layer 13 and the barrier metal 9 covering the conductive layer 13 are formed in the trench 12. Here, the conductive layer 13 is a layer which is shaped into the bit line contact 8 in a subsequent process.

The conductive layer 13 and the barrier metal 9 are formed by, e.g., following process. Firstly, a material film of the conductive layer 13 such as W, etc., and a material film of the barrier metal 9 such as Ti or TiN, etc., are sequentially embedded into the trench 12 by a PVD method, a CVD method or an ALD (Atomic Layer Deposition) method, etc. Subsequently, portions of the material films outside of the trench 12 are removed by planarization such as CMP (Chemical Mechanical Polishing), etc., thereby processing into the conductive layer 13 and the barrier metal 9.

In addition, although it is not shown in FIGS. 5A to 5C, the barrier metal 9 and the active region 2 including the source/drain region 5 in the semiconductor substrate 1 are reacted by heat, which results in that a below-described silicide layer is formed.

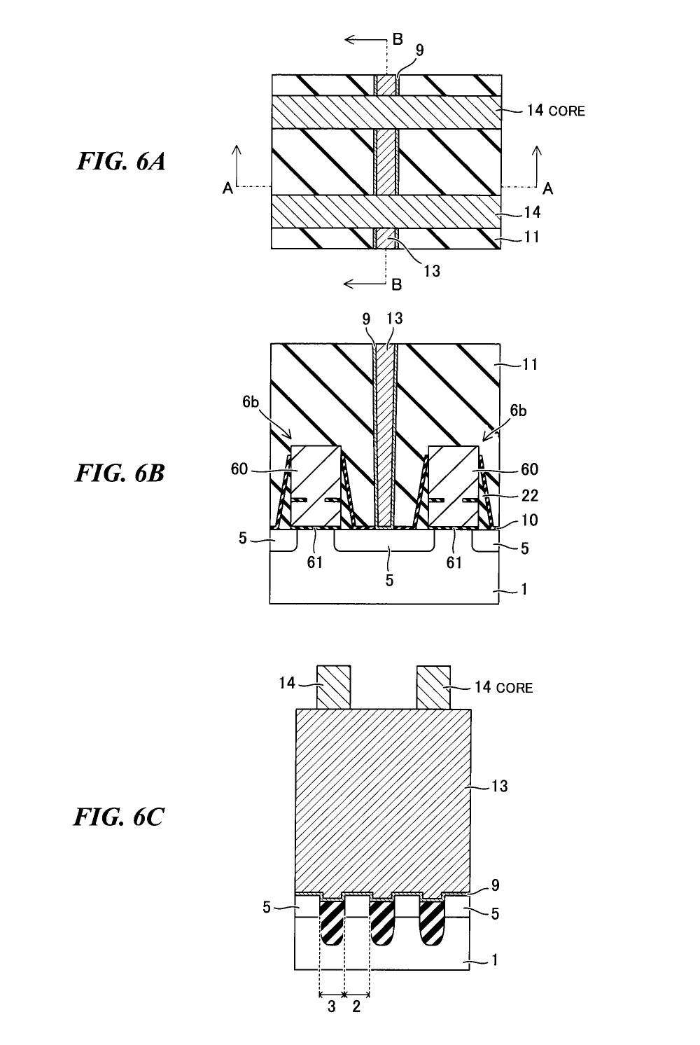

Next, as shown in FIGS. 6A to 6C, a core 14 used for a sidewall pattern transfer process is formed on the insulating layer 11. The core 14 has a linear pattern of which the longitudinal direction corresponds to a channel direction of the memory cell transistor 4 (a horizontal direction in FIG. 6A).

The core 14 is formed by, e.g., following method. Firstly, a material film of the core 14 such as polycrystalline Si, SiN, TEOS or amorphous carbon, etc., is formed on the insulating layer 11, the barrier metal 9 and the conductive layer 13 by a CVD (Chemical Vapor Deposition) method, etc. After that, the material film is patterned using the photolithography method and the RIE method for shape into the core 14. Note that, a width of the core 14 may be thinned by applying slimming treatment thereto.

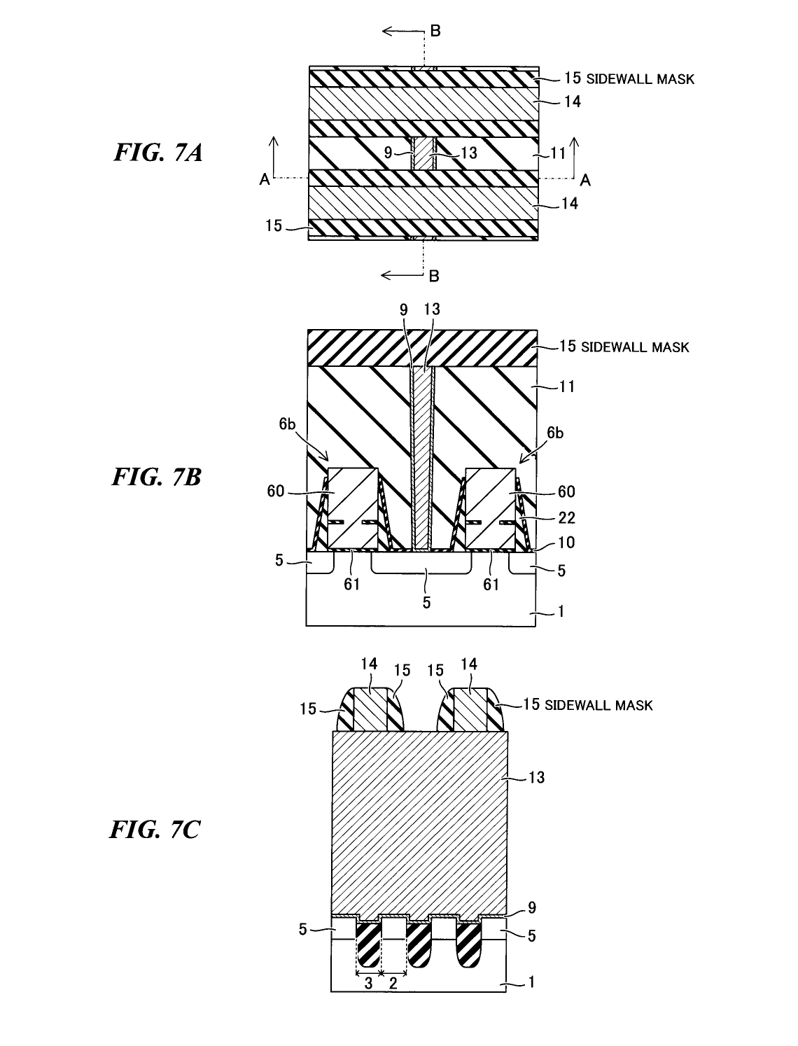

Next, as shown in FIGS. 7A to 7C, sidewall masks 15 are formed on both side faces of the core 14.

The sidewall masks 15 are formed by, e.g., following method. Firstly, a material film of the sidewall mask 15 made of polycrystalline Si, SiN, SiO₂, TEOS or BN (Boron Nitride) film, etc., is formed by the CVD method, etc., so as to cover a surface of the core 14. After that, the material film is shaped into the sidewall masks 15 by an anisotropic etching method such as the RIE method, etc.

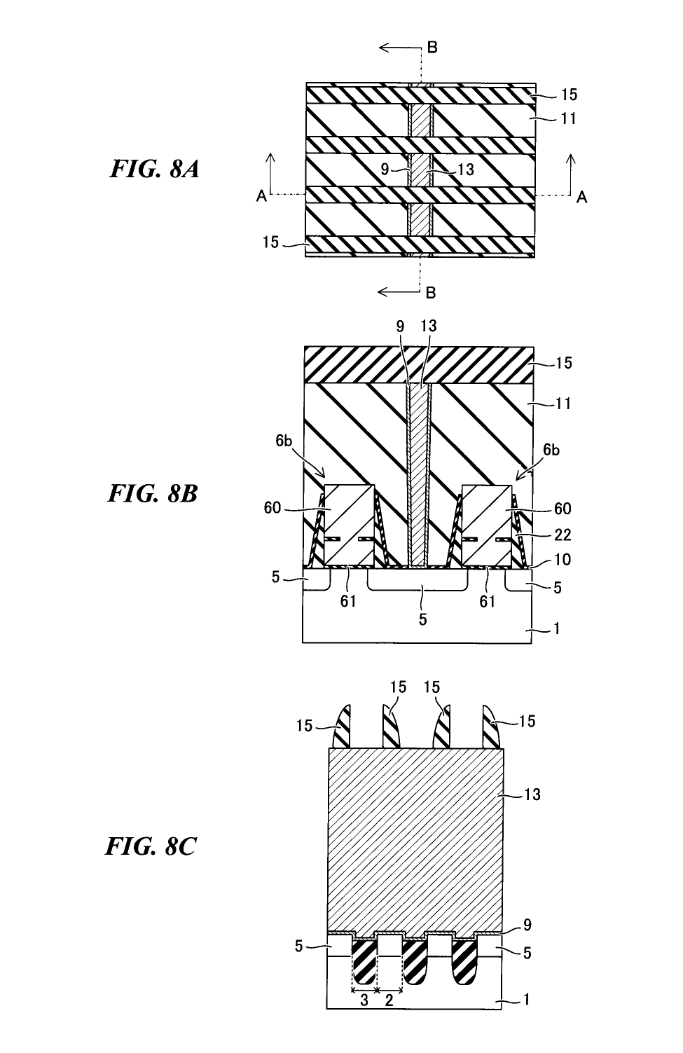

Next, as shown in FIGS. 8A to 8C, the core 14 is selectively removed by the RIE method or wet treatment, etc., while leaving the sidewall masks 15.

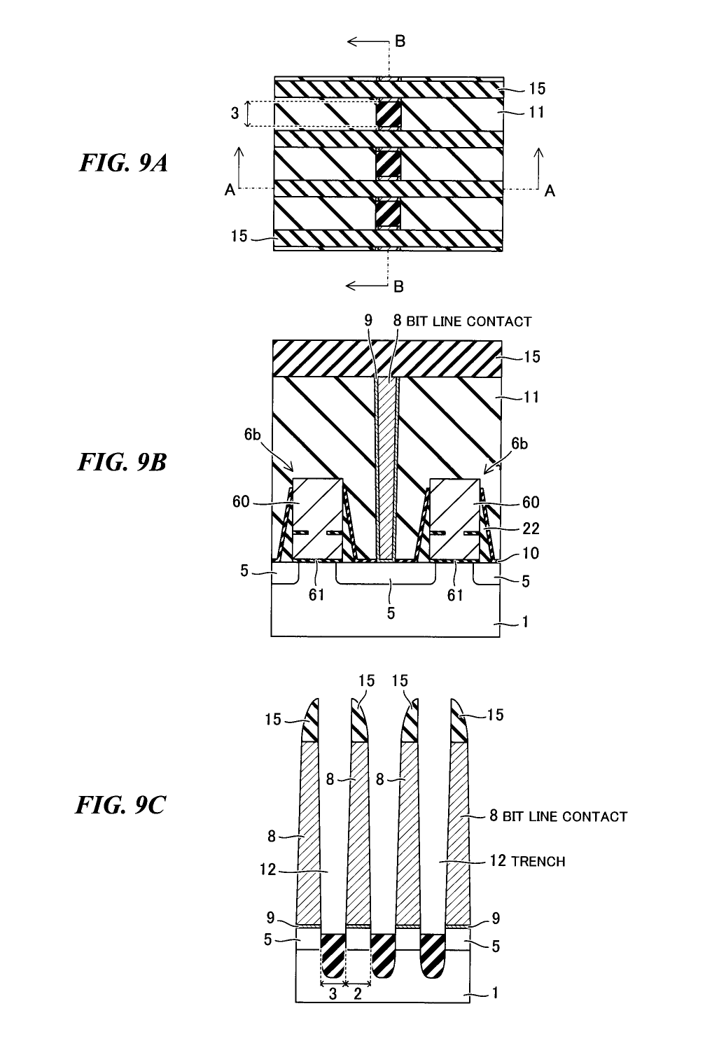

Next, as shown in FIGS. 9A to 9C, the conductive layer 13 and the barrier metal 9 are etched using the sidewall masks 15 as an etching mask, which results in that the conductive layer 13 is shaped into the bit line contact 8. The etching is performed by the RIE method, etc.

At this time, as shown in FIG. 9C, a diameter of bottom of trench formed in the conductive layer 13, which is a region in the trench 12 where the conductive layer 13 has been removed, is smaller than a diameter near opening thereof due to the etching nature. Therefore, a vertical cross sectional shape of at least a lower portion of the bit line contact 8 in the channel width direction becomes a skirt shape.

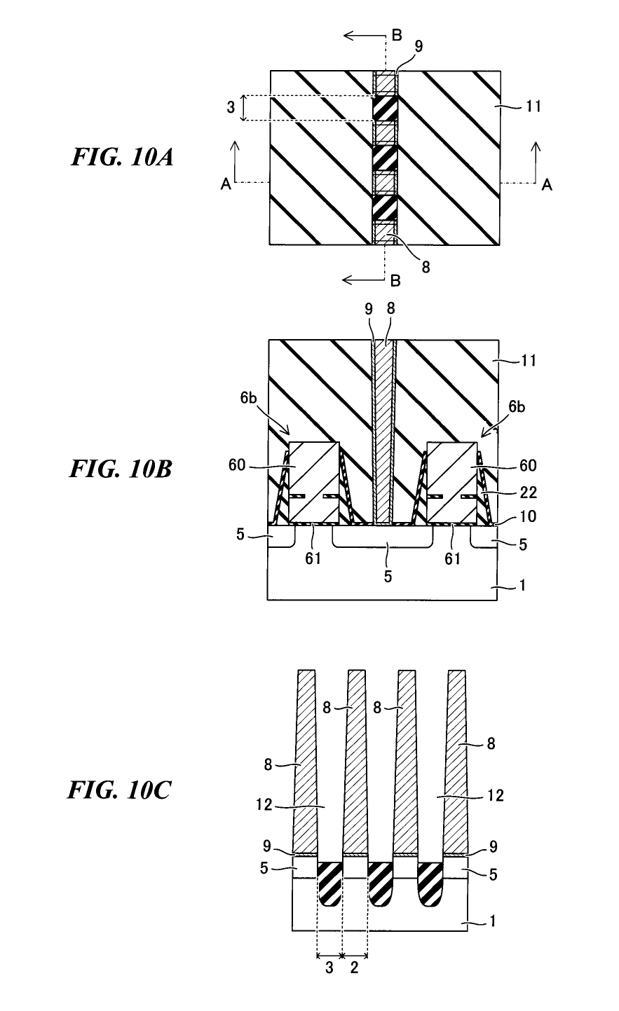

Next, as shown in FIGS. 10A to 10C, the sidewall masks 15 are removed by the wet treatment, etc.

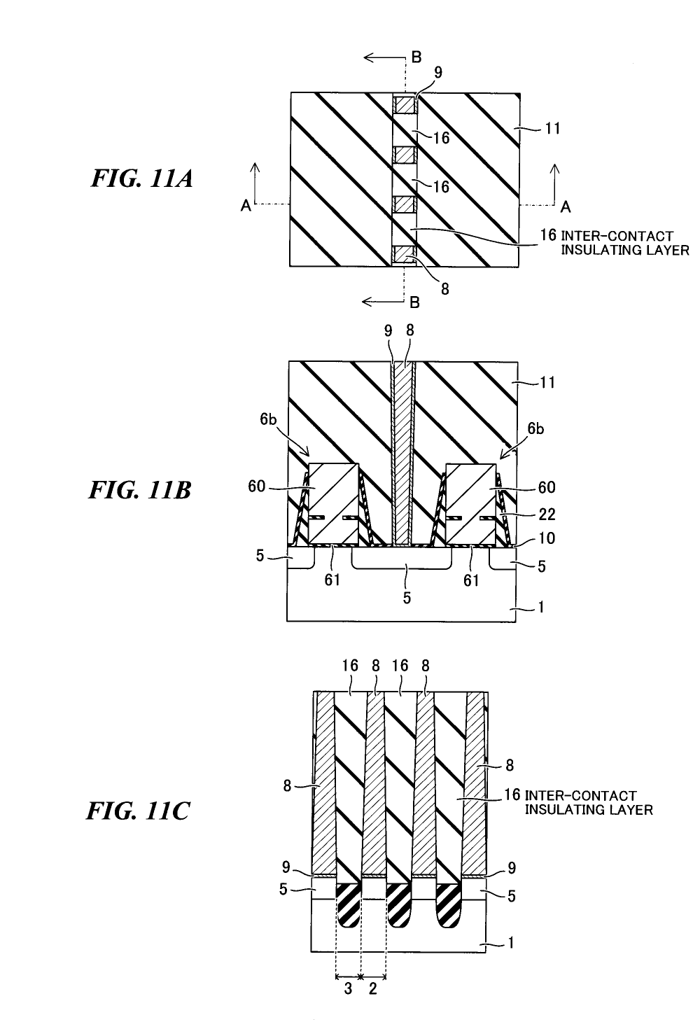

Next, as shown in FIGS. 11A to 11C, an insulating material is embedded into a region in the trench 12 where the conductive layer 13 has been removed, thereby forming the inter-contact insulating layer 16.

The inter-contact insulating layer 16 is formed by, e.g., following method. Firstly, by the CVD method or ALD, etc., a material film of the inter-contact insulating layer 16 is embedded into the region in the trench 12 where the conductive layer 13 has been removed. Subsequently, a portion of the material film outside of the trench 12 is removed by planarization such as CMP, etc., thereby shaping into inter-contact insulating layer 16. Here, as a material film of the inter-contact insulating layer 16, it is possible to use a film made of the same material as the insulating layer 11.

Alternatively, the inter-contact insulating layer 16 may be formed by embedding an insulating film into the region in the trench 12 where the conductive layer 13 has been removed while leaving the sidewall masks 15 without removing and by planarizing the insulating material together with the sidewall masks 15 by CMP using the bit line contact 8 as a stopper.

Note that, the source line contact 7 may be formed by the same method as the bit line contact 8.

### Effect of the First Embodiment

According to the first embodiment, the vertical cross sectional shape of the lower portion of the bit line contact 8 in the channel width direction can be formed in a skirt shape. Therefore, compared with a conventional bit line contact in which a diameter of the bottom portion is smaller than that of the upper portion, the connected area of the bit line contact with a source/drain region can be increased with respect to the pitch of the bit line contact, thereby reducing the electric resistance of the connected portion.

In addition, since the bit line contact 8 is formed by etching the conductive layer 13 made of a conductive material without using a conventional method in which a conducive material is embedded into a contact hole, it is possible to prevent generation of void or seam in the bit line contact caused by the embedding failure of the conductive material into the contact hole. As a result, it is possible to suppress an increase in the electric resistance in the bit line contact.

In addition, since the bit line contact 8 is formed using the sidewall pattern transfer process, it is possible to form the bit line contact 8 having a microscopic pattern.

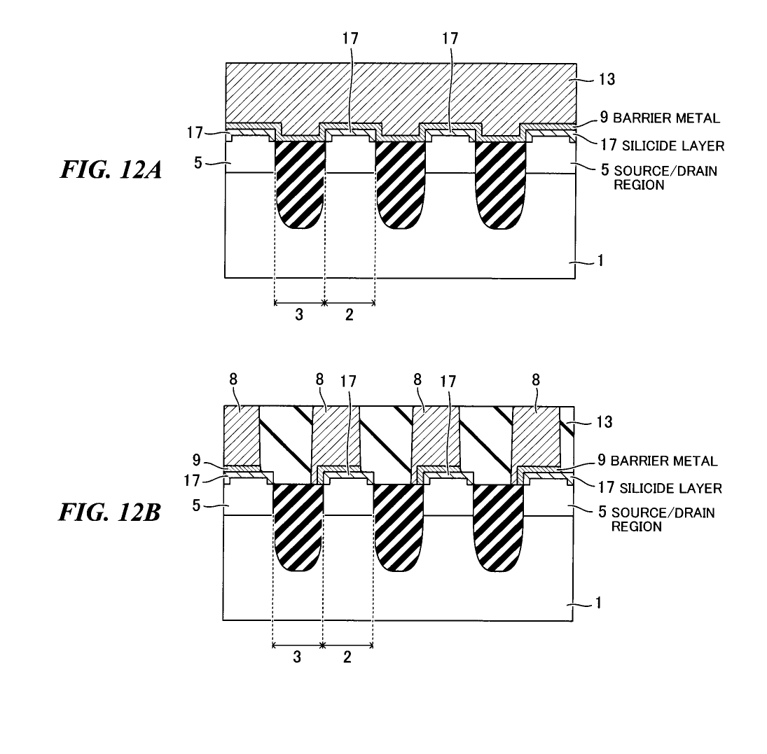

In addition, after the processes for forming conductive layer 13 and the barrier metal 9 shown in FIGS. 5A to 5C, the barrier metal 9 and the active region 2 including the source/drain region 5 in the semiconductor substrate 1 are reacted by heat treatment, which results in that a silicide layer 17 is formed. FIGS. 12A and 12B are enlarged cross sectional views showing a periphery of the silicide layer 17. The cross sections in FIGS. 12A and 12B correspond to that in FIGS. 3C and 11C, respectively.

As shown in FIG. 12A, since the barrier metal 9 covers the upper surface of the source/drain region 5 and a region of side faces thereof above the upper surface of the element isolation region 3 in the trench 12, the silicide layer 17 is formed not only on the upper surface of the source/drain region 5 but also on the entire region above the upper surface of the element isolation region 3. As a result, it is possible to effectively reduce the electric resistance of the source/drain region 5.

Therefore, as shown in FIG. 12B, even if the bit line contact 8 formed in a subsequent process is formed shifted from the active region 2 in the channel width direction, the silicide layer 17 is formed on the entire region of the upper surface of the source/drain region 5 and on the region of the side faces thereof above the upper surface of the element isolation region 3 in a region of the source/drain region 5 in a channel width direction including a region where the bit line contact 8 is connected. As a result, regardless of a formation position of the bit line contact 8, it is possible to effectively reduce the electric resistance of the source/drain region 5.

Note that, when the position of the upper surface of the element isolation region 3 is higher than a position of the upper surface of the region of the semiconductor substrate 1 including the source/drain region 5, since the region of the side faces of the source/drain region 5 above the upper surface of the element isolation region 3 does not exist, the silicide layer 17 is formed on the entire region of the upper surface of the source/drain region 5 in the region of the source/drain region 5 in the channel width direction including a region where the bit line contact 8 is connected.

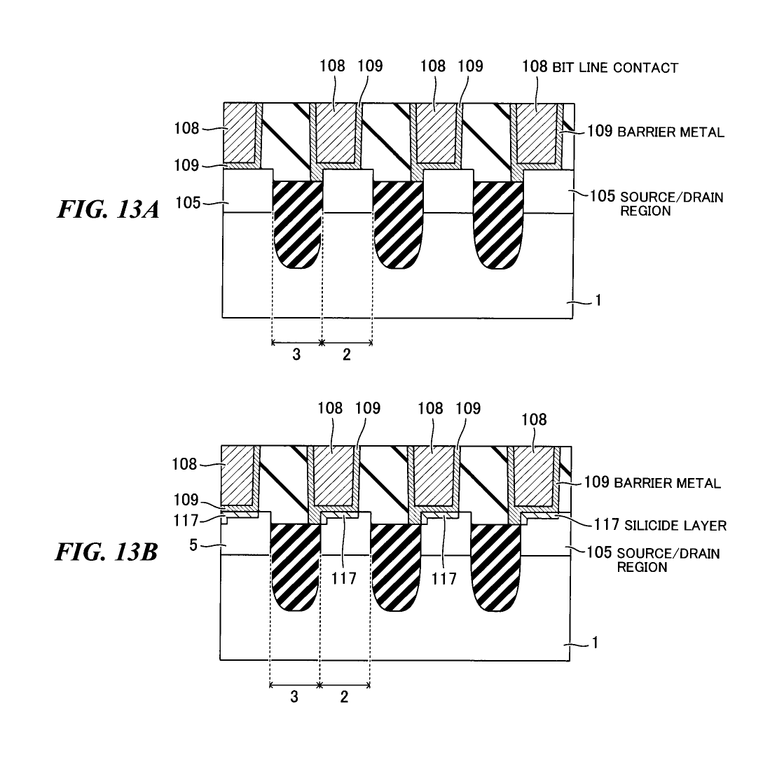

FIGS. 13A and 13B are enlarged cross sectional views showing a periphery of the silicide layer 117 of a conventional semiconductor memory device having a bit line contact 108 as Comparative Example.

As shown in FIG. 13A, according to a conventional method, since a barrier metal 109 and a bit line contact 108 are formed together by embedding a conductive material into a contact hole, a formation position of the barrier metal 109 is determined by a formation position of the contact hole, i.e., a formation position of the bit line contact 108. Therefore, when the bit line contact 108 is formed shifted from an active region 2, the barrier metal 109 contacts with only a portion of the upper surface and side faces of the active region 2.

Consequently, as shown in FIG. 13B, the silicide layer 117 is formed only on a portion of the upper surface and the side face of the active region 2, thus, it is not possible to effectively reduce the electric resistance of a source/drain region 105.

Furthermore, according to the present embodiment, since a method of embedding a conductive material into the contact hole is not used when the bit line contact is formed, it is possible to prevent the problem in the conventional method caused by an impurity at the bottom of the contact hole.

When an aspect ratio of the contact hole is large, it is difficult to remove the impurity at the bottom of the contact hole, and for example, there is a possibility that an impurity is mixed in the silicide layer formed on the source/drain region, which results in an increase in the electric resistance at the connected portion of the bit line contact with the source/drain region.

In addition, according to the present embodiment, since it is possible to reduce the electric resistance of the bit line contact 8, it is possible to suppress a problem called High Flyer in which an average value of the electric resistance of the bit line contact in the whole device is sharply increased with increasing the number of the bit line contacts to be a measurement object of electric resistivity, which is caused by the increase in the number of the high-resistance bit line contacts.

### Second Embodiment

The second embodiment is different from the first embodiment in that there is a variation in the pitch of the active region 2. Note that, the explanations will be omitted or simplified for other points which are the same as the first embodiment.

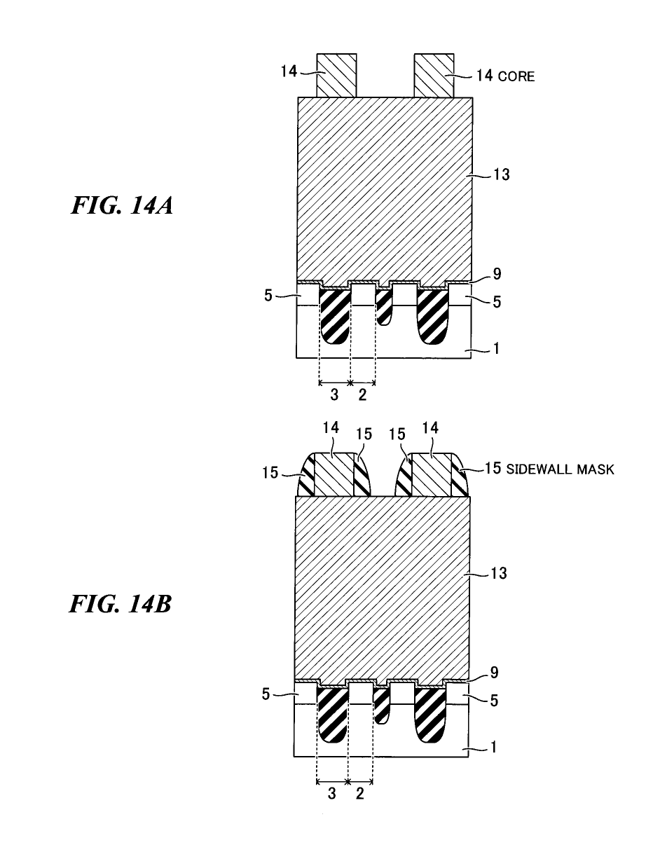

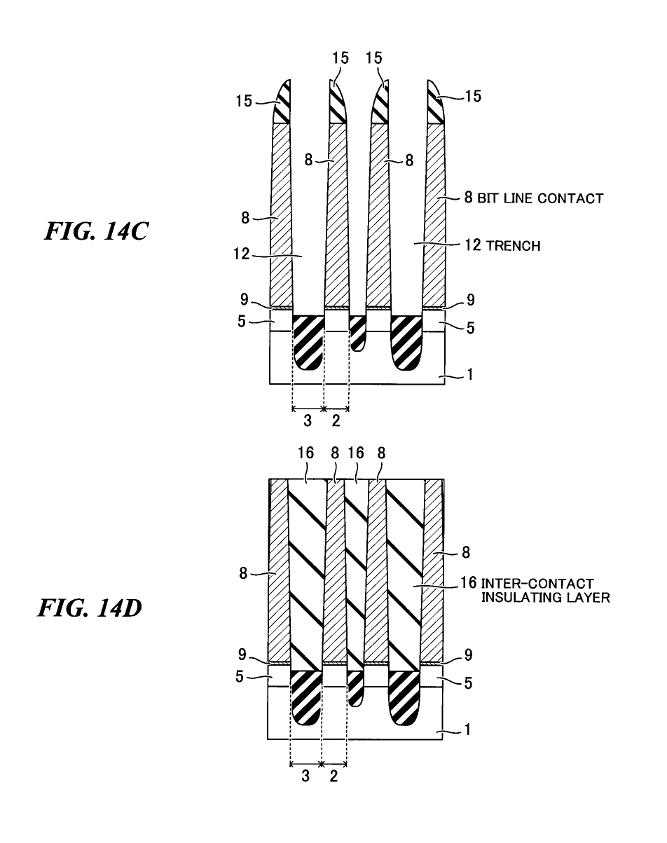

FIGS. 14A to 14D are cross sectional views showing processes for fabricating the semiconductor memory device according to a second embodiment.

Firstly, processes until the process, shown in FIGS. 3 to 5, for forming the conductive layer 13 and the barrier metal 9 are carried out in the same way as the first embodiment. In this regard, however, there is a variation in the pitch of the active region 2 in the present embodiment. The variation in the pitch of the active region 2 is generated when, for example, the variation is generated in a pattern of an etching mask which is used for forming a trench for the element isolation region 3.

Next, as shown in FIG. 14A, the core 14 is formed on the insulating layer 11. At this time, a pattern in view of the variation in the pitch of the active region 2 is formed on the core 14 by a Feed Forward method which is one of APC (Advance Process Control).

In detail, for example, after forming a trench for the element isolation region 3 in the semiconductor substrate 1, the variation in the pitch of the active region 2 is measured by CDSEM (Critical Dimension Scanning Electron Microscope), etc., and a pattern of a sidewall mask is back-calculated such that a bit line contact accurately connected to the active region 2 with a varied pitch can be formed. Furthermore, a pattern of the core 14 is back-calculated from the calculated sidewall mask pattern, thereby determining a slimming amount of the core 14.

Next, as shown in FIG. 14B, the side wall masks 15 are formed on both side faces of the core 14.

Next, as shown in FIG. 14C, the core 14 is selectively removed while leaving the sidewall masks 15, then, the conductive layer 13 and the barrier metal 9 are etched using the sidewall masks 15 as an etching mask, which results in that the conductive layer 13 is shaped into the bit line contact 8.

At this time, each bit line contact 8 is accurately connected to each region of the active region 2 with a varied pitch by the APC.

Next, as shown in FIG. 14D, after removing the sidewall masks 15, an insulating material is embedded into a region in the trench 12 where the conductive layer 13 has been removed, thereby forming the inter-contact insulating layer 16.

### Effect of the Second Embodiment

According to the conventional method, when the variation is generated in the pitch of the active region, since it is difficult to control a pitch period of the bit line contact, it is not possible to accurately connect the bit line contact to the active region. If the bit line contact is formed shifted from the active region, the connected area of the bit line contact with the source/drain region is decreased, which results in an increase in the electric resistance at the connected portion. Furthermore, when a portion shifted from the active region of the bit line contact enters the element isolation region and is formed at a position lower than the source/drain region, a junction leakage may occur.

On the other hand, according to the second embodiment, even when the variation is generated in the pitch of the active region 2, it is possible to accurately connect the bit line contact 8 to each region of the active region 2 by using the sidewall pattern transfer process which is controlled by APC. Therefore, it is possible to suppress the increase in the electrical resistance at the connected portion of the bit line contact with the source/drain region and the generation of the junction leakage, etc.

In addition, according to the present embodiment, for example, it is possible to connect the bit line contact 8 to each region of the active region 2 with a variation within 10% even in a portion where a half-pitch (which is the half of the pitch) of the active region 2 is shifted by more than 15% in the channel width direction from the designed value.

Note that, even when there is no large variation in the pitch of the active region 2, it is possible to apply the present embodiment.

### Third Embodiment

The third embodiment is different from the first embodiment in that patterning is carried out by a normal photolithography method without using the sidewall pattern transfer process when the conductive layer 13 is shaped into a bit line contact. Note that, the explanations will be omitted or simplified for other points which are the same as the first embodiment.

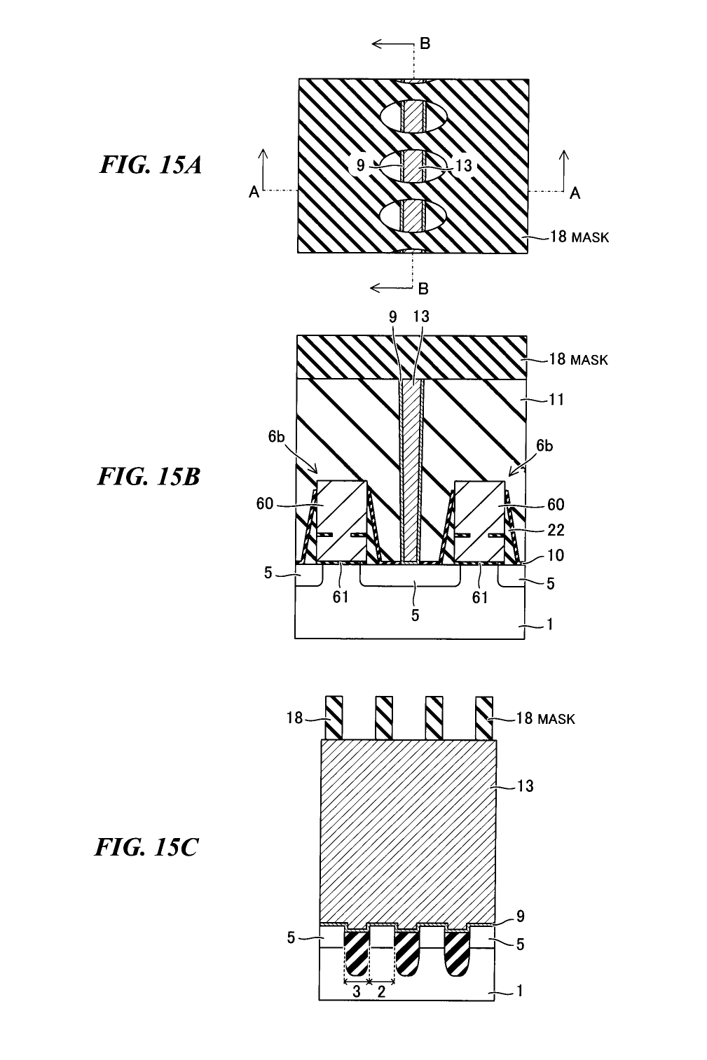

FIGS. 15 to 17 are views showing processes for fabricating the semiconductor memory device 100 according to a third embodiment. In FIGS. 15 to 17, FIGS. 15A to 17A are top views showing a vicinity of a region where a below-described bit line contact 19 is formed. In addition, FIGS. 15B to 17B are cross sectional views of the regions shown in FIGS. 15A to 17A taken on line A-A, respectively. In addition, FIGS. 15C to 17C are cross sectional views of the region shown in FIGS. 15A to 17A taken on line B-B, respectively. Note that, the lines A-A and B-B in FIGS. 15A to 17A correspond to lines A-A and B-B in FIG. 1, respectively.

Firstly, processes until the process, shown in FIGS. 3 to 5, for forming the conductive layer 13 and the barrier metal 9 are carried out in the same way as the first embodiment.

Next, as shown in FIGS. 15A to 15C, a mask 18 having a predetermined opening pattern formed by the photolithography method is formed. The predetermined opening pattern is, e.g., a pattern in an oval shape of which the longitudinal direction corresponds to the channel direction. Note that, a dimension of the opening pattern of the mask 18 may be reduced by RELACS (Resolution Enhancement Lithography Assisted by Chemical Shrink), etc.

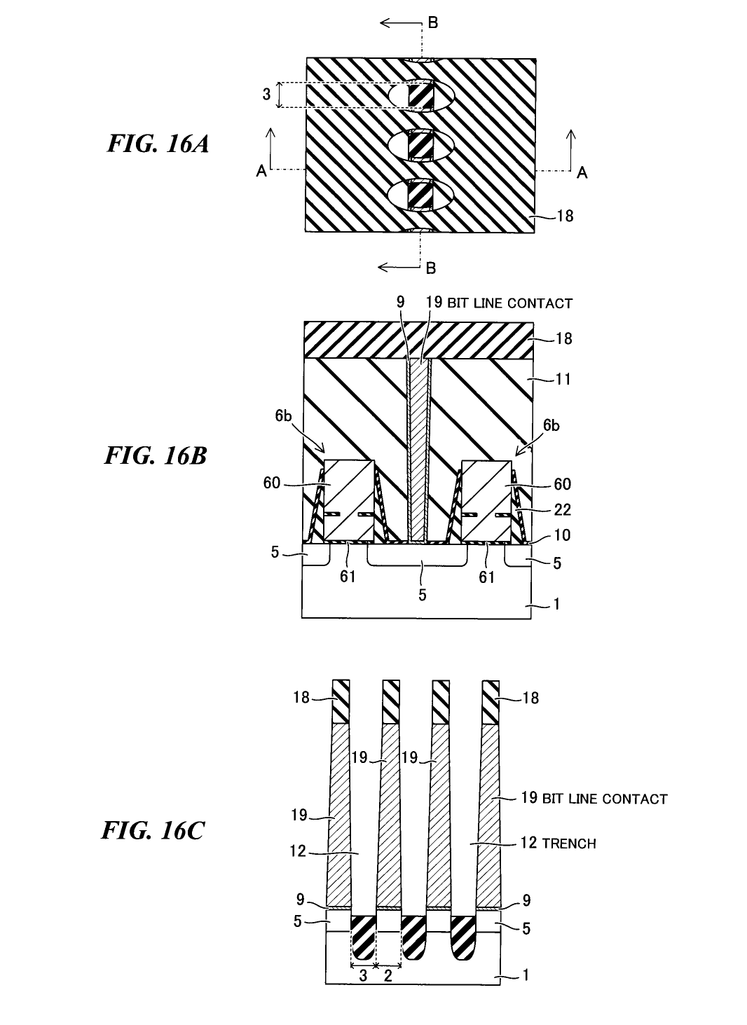

Next, as shown in FIGS. 16A to 16C, the conductive layer 13 and the barrier metal 9 are etched using the mask 18 as an etching mask, which results in that the conductive layer 13 is shaped into the bit line contact 19.

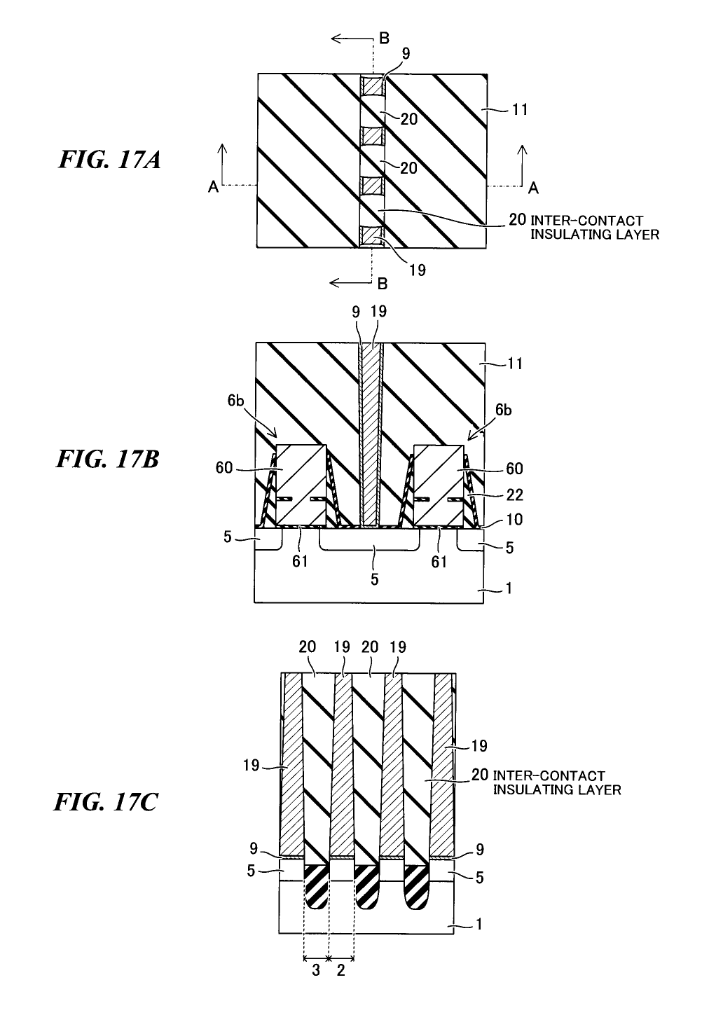

Next, as shown in FIGS. 17A to 17C, after removing the mask 18, an insulating material is embedded into a region in the trench 12 where the conductive layer 13 has been removed, thereby forming an inter-contact insulating layer 20.

At this time, when the mask 18 has an opening pattern in an oval shape, since a pattern shape of a trench formed in the conductive layer 13 (a region in the trench 12 where the conductive layer 13 has been removed) becomes a barrel-shape curved outwardly in the channel width direction, a pattern of the inter-contact insulating layer 20 also becomes a barrel-shape curved outwardly in the channel width direction. Therefore, the bit line contact 19 shaped from the conductive layer 13 has a pattern curved inwardly in the channel width direction.

### Effect of the Third Embodiment

According to the third embodiment, even when the patterning is carried out by the normal photolithography method, a vertical cross sectional shape of a lower portion of a bit line contact in the channel width direction can be formed in a skirt shape, and accordingly, it is possible to obtain the same effect as the first embodiment.

In addition, since the bit line contact 8 is formed by etching the conductive layer 13 made of a conductive material without using a conventional method in which a conductive material is embedded into a contact hole, the same effect as the first embodiment is accordingly obtained.

### Fourth Embodiment

The fourth embodiment is different from the first embodiment in that an air gap is formed in the inter-contact insulating layer. Note that, the explanations will be omitted or simplified for other points which are the same as the first embodiment.

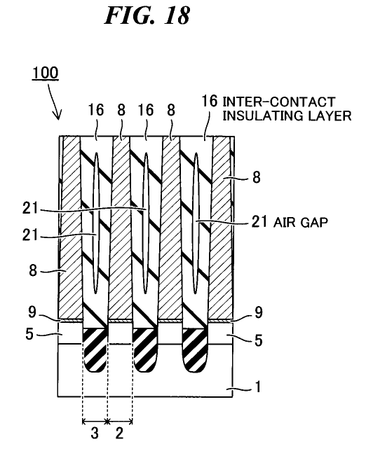

FIG. 18 is a cross sectional view showing the semiconductor memory device according to a fourth embodiment. The cross section in FIG. 18 corresponds to that in FIG. 2B.

The inter-contact insulating layer 16 in the present embodiment includes an air gap 21.

In a process for forming the inter-contact insulating layer 16 in the first embodiment (see FIG. 11), it is possible to intentionally form the air gap 21 in the inter-contact insulating layer 16 by embedding an insulating material into the region in the trench 12 where the conductive layer 13 has been removed by using an insulating film formation method with bad embedding characteristics such as the plasma CVD method or a HDP (High Density Plasma) method, etc.

### Effect of the Fourth Embodiment

According to the fourth embodiment, by intentionally forming the air gap 21 in the inter-contact insulating layer 16, it is possible to improve voltage endurance characteristics between the adjacent bit line contacts 8.

### Other Embodiments

It should be noted that the present invention is not intended to be limited to the above-mentioned first to fourth embodiments, and the various kinds of changes thereof can be implemented by those skilled in the art without departing from the gist of the invention.

In addition, the constituent elements of the above-mentioned embodiments can be arbitrarily combined with each other without departing from the gist of the invention.

What is claimed is:

1. A semiconductor memory device, comprising:
a semiconductor substrate having an active region divided by an element isolation region;
a plurality of stacked-gate type memory cell transistors connected in series on the active region;
select transistors connected to both ends of the plurality of memory cell transistors on the active region; and
a bit line contact connected to a drain region belonging to the select transistor in the active region, a vertical cross sectional shape of a lower portion of the bit line contact in a channel width direction of the plurality of memory cell transistors being in a skirt shape.

2. The semiconductor memory device according to claim 1, wherein, in a region of the drain region in the channel width direction including a region to be connected to the bit line contact, a silicide layer is formed on the entire region of an upper surface of the drain region and on a region of a side face thereof above an upper surface of the element isolation region.

3. The semiconductor memory device according to claim 2, further comprising:
another plurality of stacked-gate type memory cell transistors connected in series on another active region adjacent to the active region via the element isolation region;
other select transistors connected to both ends of the other plurality of memory cell transistors on the other active region;
another bit line contact connected to another drain region belonging to the other select transistor in the other active region, a vertical cross sectional shape of a lower portion of the other bit line contact in a channel width direction of the other plurality of memory cell transistors being in a skirt shape; and
an inter-contact insulating layer formed between the bit line contact and the other bit line contact so as to include an air gap.

4. The semiconductor memory device according to claim 3, wherein the bit line contact has a pattern curved inwardly in the channel width direction.

5. The semiconductor memory device according to claim 1, further comprising:
another plurality of stacked-gate type memory cell transistors connected in series on another active region adjacent to the active region via the element isolation region;
other select transistors connected to both ends of the other plurality of memory cell transistors on the other active region;
another bit line contact connected to another drain region belonging to the other select transistor in the another active region, a vertical cross sectional shape of a lower portion of the other bit line contact in a channel width direction of the other plurality of memory cell transistors being in a skirt shape; and
an inter-contact insulating layer formed between the bit line contact and the other bit line contact so as to include an air gap.

6. The semiconductor memory device according to claim 1, wherein the bit line contact has a pattern curved inwardly in the channel width direction.

7. A method of fabricating a semiconductor memory device, comprising:
forming a plurality of stacked-gate type memory cell transistors on an active region in a semiconductor substrate so as to be connected in series, select transistors on the active region so as to be connected to both ends of the plurality of memory cell transistors, a drain region belonging to the select transistor in the active region, and an insulating layer covering the plurality of memory cell transistors and the select transistors;
forming a trench in a region of the insulating layer including a region on the drain region, the trench having a pattern of which a longitudinal direction corresponds to a channel width direction of the plurality of memory cell transistors;
embedding a conductive material into the trench;
shaping the conductive material into a bit line contact connected on the drain region by applying etching; and
embedding an insulating material in a region of the trench where the conductive material has been removed by the shaping.

8. The method of fabricating a semiconductor memory device according to claim 7, wherein a silicide layer is formed on a surface of the drain region by silicidation reaction generated between the conductive material and the drain region.

9. A method of fabricating a semiconductor memory device, comprising:
forming a plurality of first and second memory cell transistors on respective first and second active regions adjacent to each other via an element isolation region in a semiconductor substrate, first and second select transistors on the respective first and second active regions so as to be respectively connected to both ends of the plurality of first and second memory cell transistors, first and second drain regions respectively belonging to the first and second select transistors in the respective first and second active regions, and an insulating layer covering the plurality of first and second memory cell transistors and the first and second select transistors;
forming a trench in a region of the insulating layer including a region on the first and second drain regions, the trench having a pattern of which a longitudinal direction corresponds to a channel width region of the plurality of first and second memory cell transistors;
embedding a conductive material into the trench;
shaping the conductive material by etching for forming first and second bit line contacts respectively connected on the first and second drain regions; and
embedding an insulating material in a region of the trench where the conductive material has been removed by the process.

10. The method of fabricating a semiconductor memory device according to claim 9, wherein the shaping of the conductive material by etching is carried out using a sidewall pattern transfer process, the sidewall pattern transfer process comprising forming a core on the conductive material, forming sidewalls on side faces of the core and etching the conductive material using the sidewalls as a mask after removing the core.

11. The method of fabricating a semiconductor memory device according to claim 10, wherein, after forming the first and second active regions, a pitches thereof are measured, thereby determining a pattern of the core based on the pitch.

12. The method of fabricating a semiconductor memory device according to claim 10, wherein the insulating material is embedded between the first and second bit line contacts so as to include an air gap.

13. The method of fabricating a semiconductor memory device according to claim 12, wherein the insulating material is embedded by a plasma CVD method or a HDP method.

14. The method of fabricating a semiconductor memory device according to claim 9, wherein silicide layers are formed on surfaces of the first and second drain regions by silicidation reaction generated between the conductive material and the first drain region and between the conductive material and the second drain region.

15. A semiconductor memory device, comprising:
a semiconductor substrate having an active region divided by an element isolation region;
a stacked-gate type memory cell transistor on the active region;
select transistor connected to an end of the memory cell transistor on the active region; and
a bit line contact connected to a source/drain region belonging to the select transistor in the active region, a vertical cross sectional shape of a lower portion of the bit line contact in a channel width direction of the memory cell transistor being in a skirt shape.

16. The semiconductor memory device according to claim 15, wherein, in a region of the source/drain region in the channel width direction including a region to be connected to the bit line contact, a silicide layer is formed on the entire region of an upper surface of the source/drain region and on a region of a side face thereof above an upper surface of the element isolation region.

17. A method of fabricating a semiconductor memory device, comprising:
forming a stacked-gate type memory cell transistor on an active region in a semiconductor substrate, select transistor on the active region so as to be connected to an end of the memory cell transistor, a source/drain region belonging to the select transistor in the active region, and an insulating layer covering the memory cell transistor and the select transistor;
forming a trench in a region of the insulating layer including a region on the source/drain region, the trench having a pattern of which a longitudinal direction corresponds to a channel width direction of the memory cell transistor;
embedding a conductive material into the trench;
shaping the conductive material into a bit line contact connected on the source/drain region by applying etching; and
embedding an insulating material in a region of the trench where the conductive material has been removed by the shaping.

18. The method of fabricating a semiconductor memory device according to claim 17, wherein a silicide layer is formed on a surface of the source/drain region by silicidation reaction generated between the conductive material and the source/drain region.

19. A method of fabricating a semiconductor memory device, comprising:
forming first and second memory cell transistors on respective first and second active regions adjacent to each other via an element isolation region in a semiconductor substrate, first and second select transistors on the respective first and second active regions so as to be respectively connected to ends of the first and second memory cell transistors, first and second source/drain regions respectively belonging to the first and second select transistors in the respective first and second active regions, and an insulating layer covering the first and second memory cell transistors and the first and second select transistors;
forming a trench in a region of the insulating layer including a region on the first and second source/drain regions, the trench having a pattern of which a longitudinal direction corresponds to a channel width region of the first and second memory cell transistors;
embedding a conductive material into the trench;
shaping the conductive material by etching for forming first and second bit line contacts respectively connected on the first and second source/drain regions; and
embedding an insulating material in a region of the trench where the conductive material has been removed by the process.

20. The method of fabricating a semiconductor memory device according to claim 19, wherein the shaping of the conductive material by etching is carried out using a sidewall pattern transfer process, the sidewall pattern transfer process comprising forming a core on the conductive material, forming sidewalls on side faces of the core and etching the conductive material using the sidewalls as a mask after removing the core.
